(19) United States
(12) Patent Application Publication
(10) Pub. No.: US 2003/0045032 A1
(43) Pub. Date: Mar. 6, 2003

(54) Leadframe, method of manufacturing the same, semiconductor device using the same, and method of manufacturing the device

(75) Inventor: Akinobu Abe, Nagano (JP)

Correspondence Address: ARMSTRONG,WESTERMAN & HATTORI, LLP, 1725 K STREET, NW., SUITE 1000, WASHINGTON, DC, 20006, US

(73) Assignee: SHINKO ELECTRIC INDUSTRIES CO., LTD., Nagano-shi (JP)

(21) Appl. No.: 10/227,293

(22) Filed: Aug. 26, 2002

(30) Foreign Application Priority Data
Aug. 31, 2001 (JP) 2001-262876

(51) Int. Cl. H01L 21/44

(52) U.S. Cl. 438/123

(57) ABSTRACT

A leadframe includes a die-pad portion disposed in a center of an opening defined by a frame portion, and a lead portion disposed around the die-pad portion. The frame portion, the die-pad portion and the lead portion are supported by an adhesive tape, and the lead portion is constituted to have a form in which a plurality of external connection terminals severally consisting of part of leads are arranged in the shape of a grid in a region between the die-pad portion and the frame portion.

### BACKGROUND OF THE INVENTION

(a) Field of the Invention

The present invention relates to leadframes used as a substrate of packages for mounting semiconductor chips. More specifically, the present invention relates to a leadframe having a lead shape adapted to multiterminal integration for use in a quad flat non-leaded package (“QFN”), a method of manufacturing the same and a method of manufacturing a semiconductor device using the same.

(b) Description of the Related Art

FIG. 1A to FIG. 1C schematically show constitutions of a leadframe according to the prior art and a semiconductor device using the same.

FIG. 1A shows a plan-view constitution of the leadframe. As illustrated therein, a band-shaped leadframe 10 includes a frame structure (a frame portion) formed with a pair of outer frames 11 extending parallel, and a pair of inner frames 12 linked to the outer frames 11 in an orthogonal direction to the outer frames. On the outer frames 11, there are provided guide holes 13 to be engaged with a conveyor mechanism upon conveying the leadframe 10. In a center of an opening defined by the frame portion 11 and 12, there is disposed a square-shaped die-pad portion 14 where a semiconductor chip is mounted. This die-pad portion 14 is supported by four support bars 15 extending from four corners of the frame portions 11 and 12. Moreover, a plurality of leads 16 extend from the frame portions 11 and 12 toward the die-pad portion 14 so as to form a comb shape. Each of the leads 16 includes an inner lead portion 16a to be electrically connected to an electrode of the semiconductor chip, and an outer lead portion (an external connection terminal) 16b to be electrically connected to a wiring on a packaging substrate such as a mother board.

FIG. 1B shows a cross-sectional structure of a semiconductor device having a QFN package structure fabricated using the foregoing leadframe 10. In a semiconductor device 20 illustrated therein, reference numeral 21 denotes a semiconductor chip mounted on the die-pad portion 14, reference numeral 22 denotes bonding wires for connecting electrodes of the semiconductor chip 21 to the inner lead portions 16a, and reference numeral 23 denotes molding resin for protecting the semiconductor chip 21, the bonding wires 22 and the like.

Upon fabrication of the above-described semiconductor device 20 (QFN package), the process basically include a step of mounting the semiconductor chip 21 on the die-pad portion 14 of the leadframe 10 (die-bonding), a step of electrically connecting the electrodes of the semiconductor chip 21 and the inner lead portions 16a of the leadframe 10 with the bonding wires 22 (wire bonding), a step of sealing the semiconductor chip 21, the bonding wires 22 and the like with the molding resin 23 (molding), a step of dividing the leadframe 10 into each package (semiconductor device 20) unit (dicing), and the like.

Upon performing wire bonding, as schematically shown in FIG. 1C, the respective inner lead portions 16a and the respective electrodes 21a on the semiconductor chip 21 are connected on a one-to-one basis using the bonding wires 22.

As mentioned previously, according to the constitution of the conventional leadframe (FIG. 1A), the respective leads 16 corresponding to the external connection terminals extend in the comb shape from the frame portions 11 and 12 toward the die-pad portion 14. Therefore, in order to further increase the number of the terminals, it is necessary to narrow lead widths and disposition intervals of the respective leads or to enlarge the size of the leadframe while maintaining the sizes or the like of the respective leads.

However, the approach to narrow the lead widths of the respective leads accompanies a difficulty in technical aspects (such as etching or stamping upon patterning the leadframe). Meanwhile, the approach to enlarge the size of the leadframe has a disadvantage of an increase in material costs.

In other words, the conventional leadframe including the comb-shaped leads (corresponding to the external connection terminals) which extend from the frame portions toward the die-pad portion poses a problem in that it is impossible to sufficiently meet the demand for multiterminal integration.

### SUMMARY OF THE INVENTION

An object of the present invention is to provide a leadframe suitable for multiterminal integration, a method of manufacturing the leadframe, a semiconductor device using the leadframe, and a method of manufacturing the semiconductor device.

To attain the above object, according to one aspect of the present invention, there is provided a leadframe including a die-pad portion disposed in a center of an opening defined by a frame portion, and a lead portion disposed around the die-pad portion. Here, the frame portion, the die-pad portion and the lead portion are supported by an adhesive tape, and the lead portion has a form in which a plurality of external connection terminals severally consisting of part of leads are arranged in the shape of a grid in a region between the die-pad portion and the frame portion.

According to the leadframe of this aspect, the plurality of external connection terminals are arranged in the shape of a grid as the lead portion in the region between the die-pad portion and the frame portion. Therefore, as compared to the conventional leadframe in which the leads (corresponding to the external connection terminals) extend in a comb-shape from the frame portions toward the die-pad portion it is possible to increase the number of terminals relatively (achievement of multiterminal integration).

Also, according to another aspect of the present invention, there is provided a method of manufacturing a leadframe, including the steps of forming by patterning a metal plate, a base frame including a plurality of unit frames linked to one another, in each of the unit frames a plurality of leads being arranged in mutually orthogonal directions in a region between a die-pad portion and a frame portion so as to link between the both portions for each semiconductor chip to be mounted, forming concave portions by half-etching at portions on one of surfaces of the base frame other than portions where the leads intersect one another, the die-pad portion and the frame portion, attaching an adhesive tape onto the surface of the base frame where the concave portions are formed, and cutting the portions of the leads where the concave portions are formed.

According to the method of manufacturing a lead frame of this aspect, there is formed a structure in which the leads are arranged discontinuously in the mutually orthogonal directions, by ultimately cutting the portions on the respective leads where the concave portions are formed. Therefore, by utilizing parts of the leads in intersecting portions of the respective leads, as external connection terminals, it is possible to realize a leadframe in which a plurality of external connection terminals are arranged in the shape of a grid in a region between the die-pad portion and the frame portion. In this way, multiterminal integration can be realized.

Furthermore, according to another aspect of the present invention, there is provided a semiconductor device comprising: a die-pad; a semiconductor chip mounted on said die-pad; a plurality of leads arranged in the shape of a grid around said die-pad; electrodes of said semiconductor chip being connected by bonding wires to upper surfaces of said leads; said semiconductor chip, said bonding wires and said leads being sealed with molding resin; and lower surfaces of said leads being exposed from a surface of said molding resin, and being formed as external connection terminals.

Moreover, according to still another aspect of the present invention, there is provided a method of manufacturing a semiconductor device using the foregoing leadframe, including the steps of mounting semiconductor chips severally on respective die-pad portions of the leadframe, electrically connecting electrodes of the respective semiconductor chips and a given number of external connection terminals among a plurality of external connection terminals constituting the corresponding lead portions of the leadframe severally using bonding wires, sealing the respective semiconductor chips, the respective bonding wires and the respective lead portions with molding resin, peeling off the adhesive tape, and dividing the leadframe mounting the respective semiconductor chips thereon into individual semiconductor devices such that each of the semiconductor devices includes one of the semiconductor chips.

### BRIEF DESCRIPTION OF THE DRAWINGS

FIG. 1A to FIG. 1C are views showing constitutions of a leadframe and a semiconductor device using the leadframe according to the prior art;

FIG. 2A and FIG. 2B are views showing a constitution of a leadframe according to one embodiment of the present invention;

FIG. 3A to FIG. 3E are cross-sectional views (in part, plan view) showing one example of a manufacturing process of the leadframe illustrated in FIG. 2A and FIG. 2B;

FIG. 4A to FIG. 4C are cross-sectional views showing another example of a manufacturing process of the leadframe illustrated in FIG. 2A and FIG. 2B;

FIG. 5 is a cross-sectional view showing one example of a semiconductor device using the leadframe illustrated in FIG. 2A and FIG. 2B;

FIG. 6A to FIG. 6E are cross-sectional views (in part, plan view) for showing one example of a manufacturing process of the semiconductor device illustrated in FIG. 5;

FIG. 7 is a cross-sectional view showing another example of a semiconductor device using the leadframe illustrated in FIG. 2A and FIG. 2B; and

FIG. 8 is a plan view showing a constitution of a leadframe according to another embodiment of the present invention.

### DESCRIPTION OF THE PREFERRED EMBODIMENTS

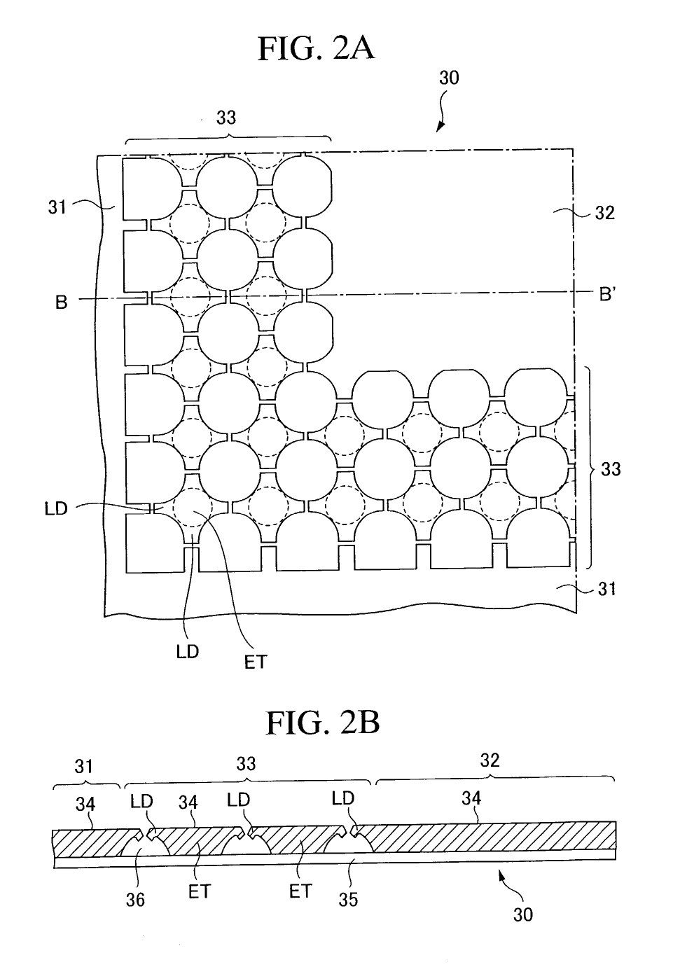

FIG. 2A and FIG. 2B schematically show a constitution of a leadframe according to one embodiment of the present invention. FIG. 2A shows a plan-view constitution of part of the leadframe (in the illustrated example, a quarter portion thereof), and FIG. 2B shows a cross-sectional constitution taken along the B-B′ line in FIG. 2A.

In FIG. 2A and FIG. 2B, reference numeral 30 denotes a leadframe used as a QFN substrate, reference numeral 31 denotes a frame portion, reference numeral 32 denotes a die-pad portion for mounting a semiconductor chip to be disposed in a center of an opening defined by the frame portion 31, reference numeral 33 denotes a lead portion disposed in a region between the frame portion 31 and the die-pad portion 32, reference numeral 34 denotes metallic films formed on surfaces of the frame portion 31, the die-pad portion 32 and the lead portion 33, and reference numeral 35 denotes an adhesive tape for supporting the frame portion 31, the die-pad portion 32 and the lead portion 33. Moreover, reference numeral 36 denotes concave portions formed by half-etching as described later.

In the lead portion 33 disposed in the region between the frame portion 31 and the die-pad portion 32, a plurality of leads LD are arranged in mutually orthogonal directions (i.e. in the shape of a grid) and in a discontinuous manner. Portions where the independently disposed leads LD intersect one another (portions surrounded by broken lines) constitute external connection terminals ET. Namely, the lead portion 33 has a form of a grid array in the region between the die-pad portion 32 and the frame portion 31, which is composed of the plurality of external connection terminals each formed of part of the respective leads LD.

In the example shown in FIG. 2A, the portions where the respective leads LD intersect one another (external connection terminals ET) are formed in larger sizes than lead widths. Such designs can be easily made in accordance with patterning of a metal plate by etching or the like. Accordingly, a wire boding process to be carried out later in a package assembly process is facilitated by forming the intersecting portions of the respective leads LD larger as described above.

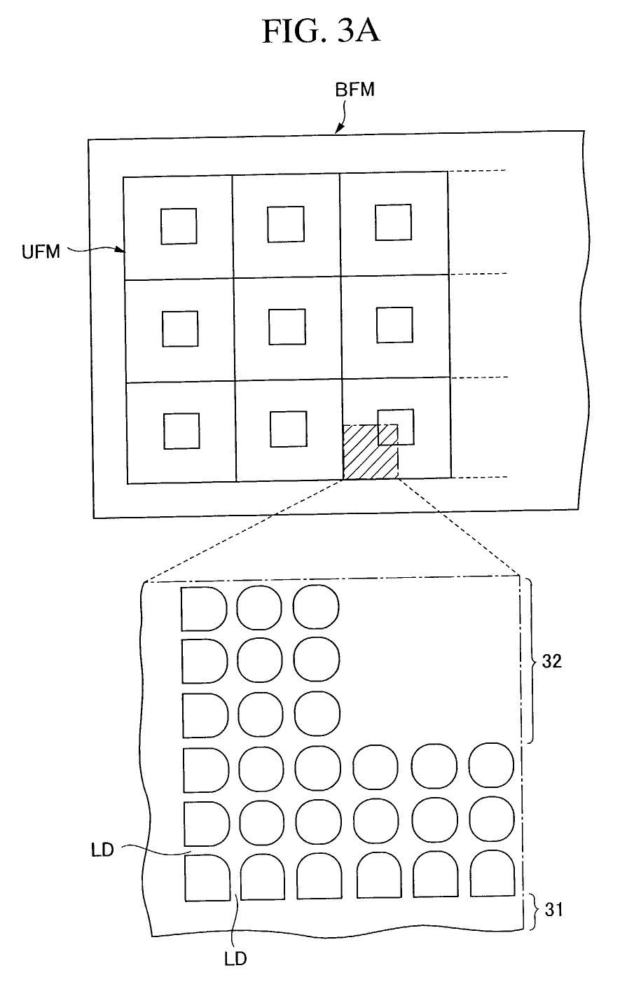

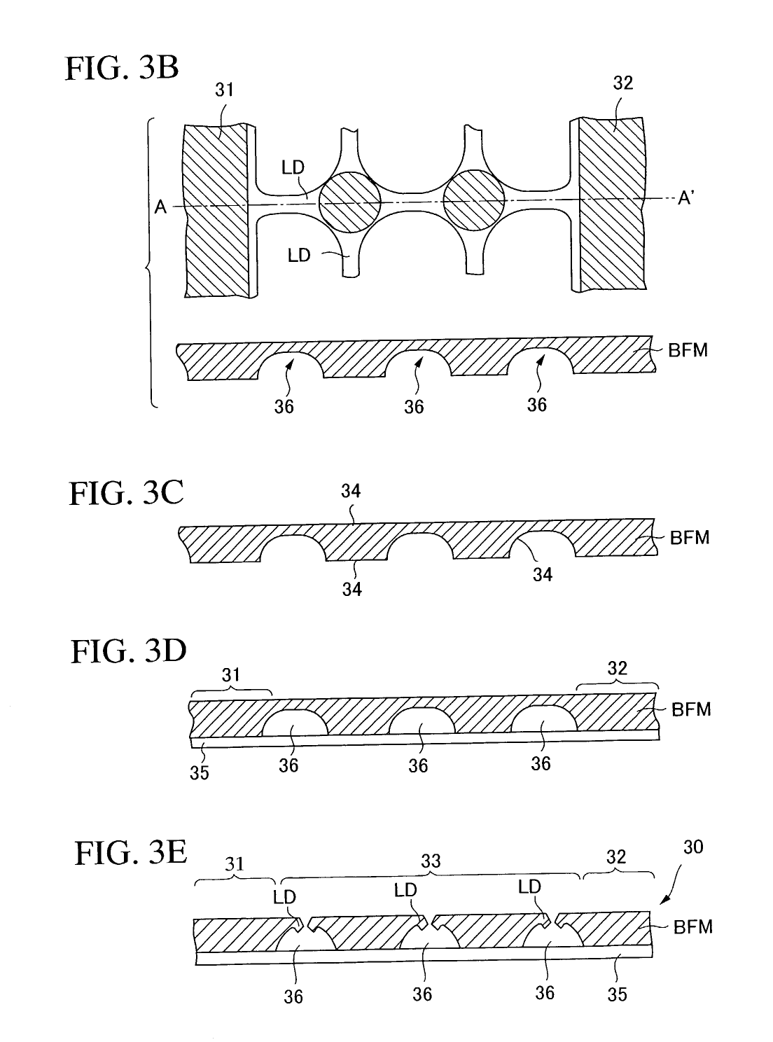

Hereinafter, a method of manufacturing the leadframe 30 according to this embodiment is described with reference to FIG. 3A to FIG. 3E, which illustrate one example of the manufacturing process in a sequential order.

In the first step (FIG. 3A), a metal plate is patterned by etching or stamping so as to form a base frame BFM.

As schematically shown in an upper side of FIG. 3A, the base frame BFM to be formed has a structure including a plurality of unit frames UFM being linked to one another and severally allotted to respective semiconductor chips to be mounted. In each of the unit frames UFM, as schematically shown in a lower part of FIG. 3A as a quarter portion thereof (a portion shown by hatching), the plurality of leads LD are continuously arranged in mutually orthogonal directions so as to link between the die-pad portion 32 and the frame portion 31.

As materials for use in the metal plate, for example, copper (Cu), Cu-based alloys, iron-nickel (Fe—Ni) or Fe—Ni-based alloys are used. Also, the thickness of the metal frame (base frame BFM) is selected to be about 200 μm.

In the next step (FIG. 3B), the concave portions 36 are formed on predetermined portions on one of the surfaces of the base frame BFM (in the illustrated example, on a lower surface in a cross-sectional constitution shown in the lower side) by half-etching.

Portions excluding the portions illustrated by hatching (the portions where the respective leads LD intersect one another, the die-pad portion 32 and the frame portion 31) in a plan-view constitution shown in the upper side in FIG. 3B are selected as the portions to form the concave portions 36 (the predetermined portions).

Note that half-etching can be performed by covering the entire surface of the base frame BFM excluding a region of the predetermined portions with a mask (not shown) and subsequently by wet etching. Also, the concave portions 36 are formed in depths of about 160 μm.

In the next step (FIG. 3C), the metallic films 34 are formed on the entire surface of the base frame BFM on which the concave portions 36 are formed, by electrolytic plating.

For example, while using the base frame BFM as a feeding layer, nickel (Ni) is plated on the surface thereof for enhancing adhesion and then palladium (Pd) is plated on the Ni layer for enhancing conductivity. Thereafter, gold (Au) flash plating is provided on the Pd layer, to thereby form the metallic films (Ni/Pd/Au) 34.

In the next step (FIG. 3D), the adhesive tape 35 made of epoxy resin, polyimide resin or the like is attached to the surface of the base frame BFM where the concave portions 36 are formed (which is a lower surface in the illustrated example) (taping).

This taping is basically performed as a remedy for preventing formation of unnecessary resin films (moldflush) upon molding in the package assembly process to be carried out at a later stage.

Furthermore, this adhesive tape 35 has a function of supporting the die-pad portion 32 and the frame portion 31, and of supporting the individual leads LD to be divided upon cutting predetermined portions of the leads LD in a later stage so as not to fall off.

In the last step (FIG. 3E), the portions of the respective leads LD where the concave portions 36 are formed are broken (cut) by stamping out with a die (a punch), for example. In this way, the leadframe 30 (FIGS. 2A and 2B) of this embodiment is fabricated.

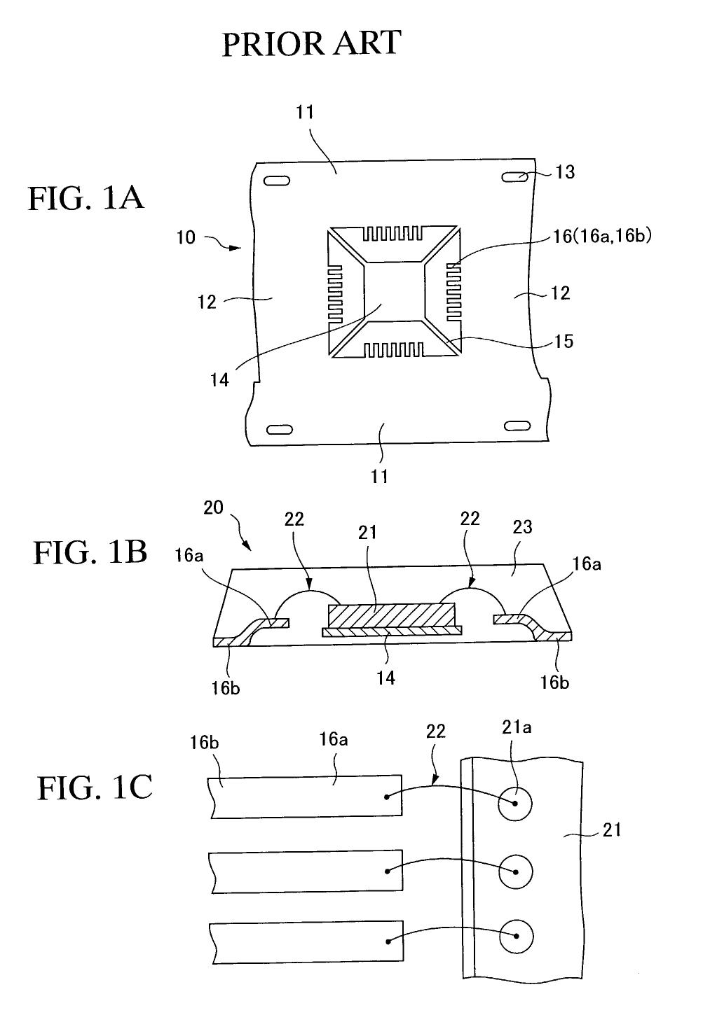

As described above, according to the leadframe 30 and the method of manufacturing the same of this embodiment, the plurality of external connection terminals ET severally consisting of part of the leads LD are arranged in the shape of a grid in the lead portion 33 disposed in the region between the die-pad portion 32 and the frame portion 31. Therefore, it is possible to relatively increase the number of terminals (multiterminal integration) as compared to the conventional leadframe (FIG. 1A) in which the leads (corresponding to the external connection terminals) extend in a comb shape from the frame portion toward the die-pad portion.

Also, where semiconductor chips are downsized along with developments in the relevant technologies and accordingly die-pad portions are scaled down, the conventional leadframe (FIG. 1A) has posed a disadvantage in cost because the bonding wires 22 for connecting the inner lead portions 16a and the semiconductor chip 21 on the die-pad portion 14 become relatively longer since the inner lead portions 16a are disposed on the side of the frame portions 11 and 12. On the contrary, according to this embodiment (FIGS. 2A and 2B), it is easily possible to increase the terminals ET in a space provided by downsizing the die-pad portion 32 (i.e. on the side of the die-pad portion 32).

Therefore, it is sufficient if the bonding wires are provided between the terminals on the side of the die-pad portion 32 and the semiconductor chip. Accordingly, the lengths of the bonding wires can be shortened as compared to the conventional leadframe, which contributes to a reduction in cost.

Also, although the conventional leadframe (FIG. 1A) requires the support bars 15 for supporting the die-pad portion 14, the present embodiment (FIGS. 2A and 2B) does not require such support bars. Accordingly, it is possible to provide the terminals ET in the space formerly occupied by the support bars 15, which contributes to a further multiterminal integration.

Furthermore, in the present embodiment (FIGS. 2A and 2B), all of the portions where the concave portions 36 of the respective leads LD are formed are cut away. However, it is also possible to select some of the portions and leave the selected portions uncut if necessary, as shown in FIG. 3D (i.e., the portion where the concave portion 36 is formed between a terminal on the side of the die-pad portion 32 and a terminal on the side of the frame portion 31 remains connected without cutting), for example. Accordingly, it is possible to use a terminal near a package line (on the side of the frame portion 31) by providing a short bonding wire between the terminal on the side of the die-pad portion 32 and the semiconductor chip. This contributes to a reduction in cost.

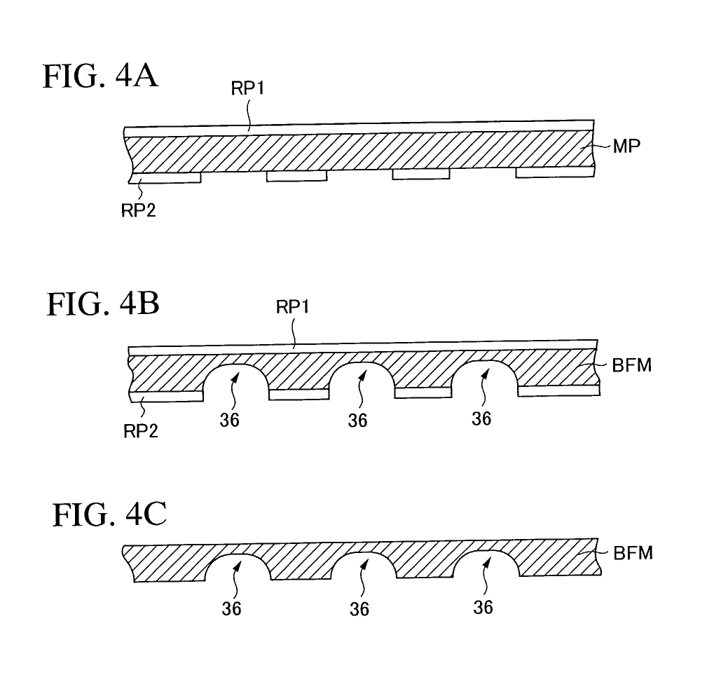

In the method of manufacturing the leadframe 30 according to the above-described embodiment, formation of the base frame BFM (FIG. 3A) and formation of the concave portions 36 (FIG. 3B) are performed in the separate steps. However, it is also possible to form the base frame BFM and the concave portions 36 in the same step. FIG. 4A to FIG. 4C illustrate one example of the manufacturing method in that case.

In the exemplified method, first, etching resist is coated on both surfaces of a metal plate MP (such as a plate made of Cu or a Cu-based alloy) and the resist is patterned using masks (not shown) patterned in accordance with given shapes, to thereby form resist patterns RP1 and RP2 (FIG. 4A).

In this case, regarding the resist pattern RP1 on the upper side (the side where a semiconductor chip is mounted), the relevant resist is patterned so as to cover the regions corresponding to the respective leads LD, the die-pad portion 32 and the frame portion 31, of the metal plate MP. On the other hand, regarding the resist pattern RP2 on the lower side, the relevant resist is patterned so as to cover the regions corresponding to portions where the respective leads LD intersect one another (the portions constituting the external connection terminals ET), the die-pad portion 32 and the frame portion 31, of the metal plate MP, and to expose the regions corresponding to the portions constituting the concave portions 36.

In this way, after the both surfaces of the metal plate MP are covered with the resist patterns RP1 and RP2, the pattern of the lead portions LD as shown in the lower side of FIG. 3A and the concave portions 36 are formed simultaneously by etching (such as wet etching) (FIG. 4B).

Thereafter, the etching resists (RP1 and RP2) are peeled off and the base frame BFM having the structure such as shown in the lower side of FIG. 3B is obtained (FIG. 4C). The subsequent steps are the same as the steps as shown in FIG. 3C and so on.

According to the method exemplified in FIG. 4A to FIG. 4C, formation of the base frame BFM and formation of the concave portions 36 are carried out in one step. Therefore, it is possible to simplify the steps as compared to the above embodiment (FIG. 2A to FIG. 3E).

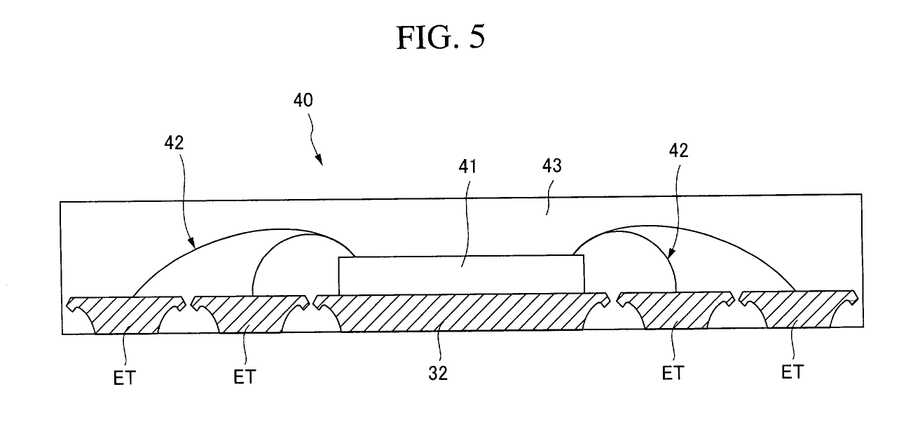

FIG. 5 schematically shows one example of a semiconductor device having a QFN package structure fabricated using the leadframe 30 of the above-described embodiment.

In FIG. 5, reference numeral 40 denotes a semiconductor device, reference numeral 41 denotes a semiconductor chip mounted on the die-pad portion 32, reference numeral 42 denotes bonding wires for connecting the plurality of external connection terminals ET and respective electrodes of the semiconductor chip 41 severally on a one-to-one basis, and reference numeral 43 denotes molding resin for protecting the semiconductor chip 41, the bonding wires 42 and the like.

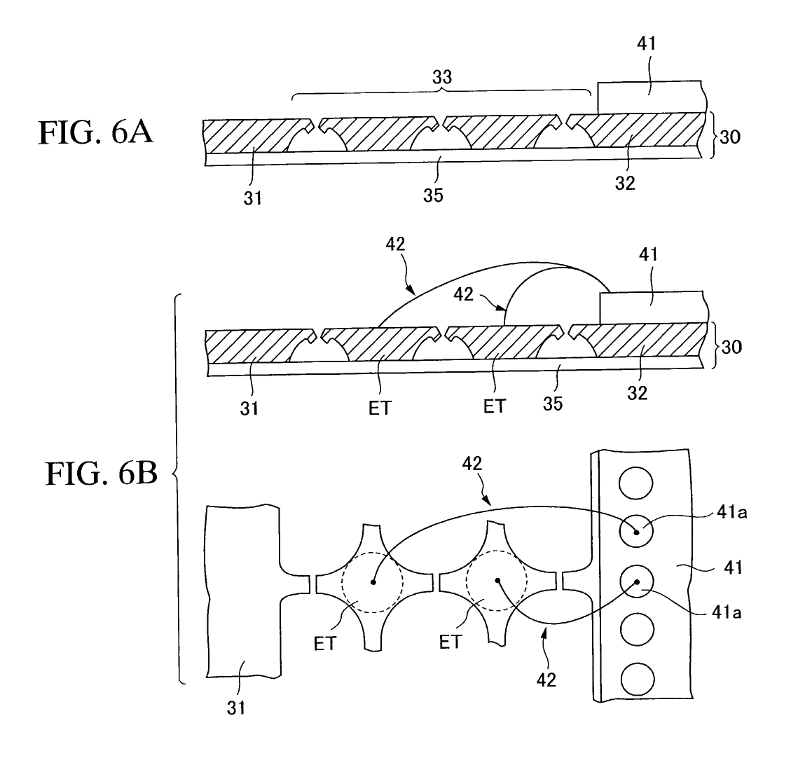

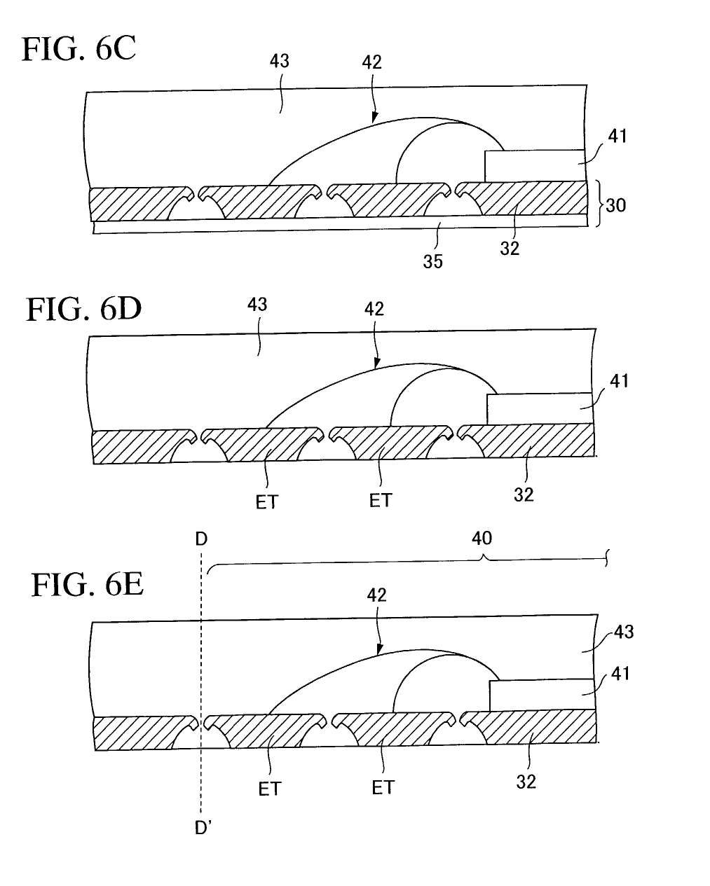

Hereinafter, a method of manufacturing the semiconductor device 40 is described with reference to FIG. 6A to FIG. 6E, which illustrate the manufacturing steps.

In the first step (FIG. 6A), the leadframe 30 is held with a holder jig (not shown) while putting downward the surface to which the adhesive tape 35 is attached, and the semiconductor chips 41 are mounted severally on the respective die-pad portions 32 of the leadframe 30. To be more precise, an adhesive such as epoxy resin is coated on the die-pad portions 32 and the back surfaces (opposite surfaces to the surfaces where the electrodes are formed) of the semiconductor chips 41 are set downward, whereby the semiconductor chips 41 are adhered to the die-pad portions 32 with the adhesive.

Note that the illustrated example shows a state where one semiconductor chip 41 is mounted on one die-pad portion 32 for the purpose of simplification.

In the next step (FIG. 6B), the electrodes of the respective semiconductor chips 41 and a given number of external connection terminals (two terminals in the illustrated example) among the plurality of external connection terminals ET constituting the relevant lead portions 33 on the lead frame 30 are electrically connected by the bonding wires 42 severally.

In this event, as schematically shown in the lower side of FIG. 6B, the respective external connection terminals ET and the respective electrodes 41a on the semiconductor chip 41 are connected severally by the bonding wires 42 on a one-to-one basis. In this way, the semiconductor chips 41 are mounted on the leadframe 30.

In the next step (FIG. 6C), the entire surface of the leadframe 30 on the side where the semiconductor chips 41 are mounted is sealed with the molding resin 43 by a mass molding. Although it is not illustrated particularly in the drawing, such sealing is performed by disposing the leadframe 30 on a lower mold of molds (a pair of upper and lower molds) and holding the leadframe 30 with the upper mold from above, and then by a thermal pressurizing treatment while filling the molding resin. Transfer molding is used as an example of sealing.

In the next step (FIG. 6D), the leadframe 30 (FIG. 6C) sealed with the molding resin 43 is taken out of the molds, and then the adhesive tape 35 is peeled off and removed from the leadframe 30.

In the last step (FIG. 6E), the leadframe is divided into package units along a dicing line D-D′ as illustrated with a broken line using a dicer or the like, such that each package unit includes one semiconductor chip 41. Thus the semiconductor device 40 (FIG. 5) is obtained.

In the above-described method of manufacturing the semiconductor device 40, resin sealing is carried out in the step of FIG. 6C in accordance with the mass molding. However, instead of the mass molding, it is also possible to apply an individual molding, which refers to a method of performing resin sealing on each semiconductor chip 41 individually.

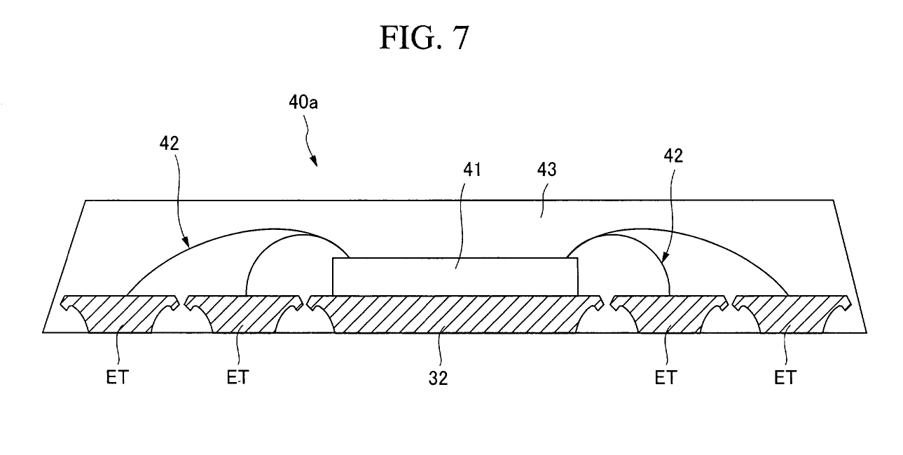

Note that, in the case where the resin sealing is carried out in accordance with the individual molding, the shape of the semiconductor device to be obtained ultimately by division into package units is formed into a form of a semiconductor device 40a as exemplified in FIG. 7.

The difference between the semiconductor device 40a shown in FIG. 7 and the semiconductor device 40 shown in FIG. 5 is a cross-sectional shape of the molding resin 43 (the former is trapezoidal and the latter is rectangular). Since other constitutions are common between the devices 40 and 40a, description thereof is omitted.

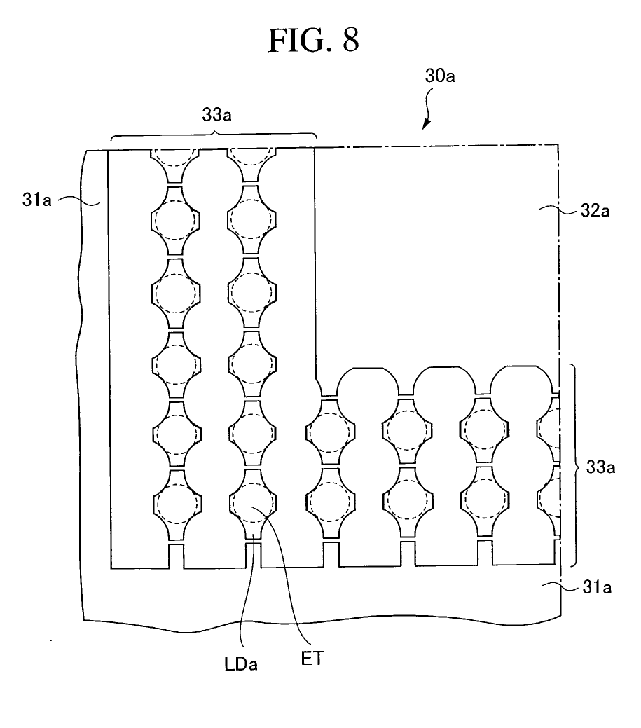

FIG. 8 schematically shows a plan-view constitution of a leadframe (a quarter portion thereof) according to another embodiment of the present invention.

A leadframe 30a according to this embodiment is different from the leadframe 30 according to the embodiment shown in FIGS. 2A and 2B in that a plurality of leads LDa are arranged discontinuously in mutually parallel directions (i.e. in one direction) in a lead portion 33a disposed in a region between a frame portion 31a and a die-pad portion 32a, and in that external connection terminals ET formed of part of the leads are provided along the respective leads LDa which are disposed independently of one another.

Since other constitutions are identical to those in the embodiment shown in FIGS. 2A and 2B, description thereof is omitted. Similarly, since the method of manufacturing the leadframe 30a is basically identical to the manufacturing method shown in FIG. 3A to FIG. 3E, description thereof is omitted.

According to this embodiment (FIG. 8), in addition to the advantages obtained by the above-described embodiment (FIG. 2A to FIG. 3E), it is possible to obtain an advantage in that the leads can be easily cut away in the last step (FIG. 3E) using a die (a punch) since the leads LDa are arranged only in one direction.

Additionally, in the above-described embodiments, description has been made regarding the leadframes 30 and 30a as examples which do not require support bars. However, as is obvious from the gist of the present invention (arranging a plurality of external connection terminals in the shape of a grid in a region between a die-pad portion and a frame portion), the present invention is similarly applicable to a leadframe including support bars as in the prior art, irrespective of presence or absence of support bars.

What is claimed is:

1. A leadframe comprising:
a die-pad portion disposed in a center of an opening defined by a frame portion;
a lead portion disposed around the die-pad portion;
said frame portion, said die-pad portion and said lead portion being supported by an adhesive tape; and
said lead portion having a form in which a plurality of external connection terminals severally consisting of part of leads are arranged in the shape of a grid in a region between said die-pad portion and said frame portion.

2. The leadframe according to claim 1, wherein a plurality of leads are discontinuously arranged in mutually orthogonal directions in the region between said die-pad portion and said frame portion, and each of said plurality of external connection terminals is formed at each intersecting portion of said leads.

3. The leadframe according to claim 1, wherein a plurality of leads are discontinuously arranged in mutually parallel directions in the region between said die-pad portion and said frame portion, and each of said plurality of external connection terminals is formed along the arrangement direction of said leads.

4. A method of manufacturing a leadframe, comprising the steps of:
forming by patterning a metal plate, a base frame including a plurality of unit frames linked to one another, in each of the unit frames a plurality of leads being arranged in mutually orthogonal directions in a region between a die-pad portion and a frame portion so as to link between the both portions for each semiconductor chip to be mounted;
forming concave portions by half-etching at portions on one of surfaces of said base frame other than portions where said leads intersect one another, said die-pad portion and said frame portion;
attaching an adhesive tape onto the surface of said base frame where the concave portions are formed; and
cutting the portions of said leads where the concave portions are formed.

5. The method according to claim 4, instead of comprising the step of forming a base frame and the step of forming concave portions, comprising the steps of:
forming first and second resists severally patterned into predetermined shapes on both surfaces of a metal plate;
forming by etching while using said first and second resists as masks, a base frame including a plurality of unit frames linked to one another, in each of the unit frames a plurality of leads being arranged in mutually orthogonal directions in a region between a die-pad portion and a frame portion so as to link between the both portions for each semiconductor chip to be mounted, and simultaneously forming concave portions at portions on one of surfaces of said base frame other than portions where said leads intersect one another, said die-pad portion and said frame portion; and
peeling off said first and second resists.

6. The method according to any one of claims 4 and 5, wherein the step of cutting the portions of said leads where the concave portions are formed includes the step of allowing portions selected from among all portions where the concave portions are formed, to remain uncut and connected.

7. A method of manufacturing a leadframe, comprising the steps of:
forming by patterning a metal plate, a base frame including a plurality of unit frames linked to one another, in each of the unit frames a plurality of leads being arranged in mutually parallel directions in a region between a die-pad portion and a frame portion so as to link between the both portions for each semiconductor chip to be mounted;
forming concave portions by half-etching at portions on one of surfaces of said base frame other than given portions of said leads, said die-pad portion and said frame portion;
attaching an adhesive tape onto the surface of said base frame where the concave portions are formed; and
cutting the portions of said leads where the concave portions are formed.

8. The method according to claim 7, instead of comprising the step of forming a base frame and the step of forming concave portions, comprising the steps of:
forming first and second resists severally patterned into predetermined shapes on both surfaces of a metal plate;
forming by etching while using said first and second resists as masks, a base frame including a plurality of unit frames linked to one another, in each of the unit frames a plurality of leads being arranged in mutually parallel directions in a region between a die-pad portion and a frame portion so as to link between the both portions for each semiconductor chip to be mounted, and simultaneously forming concave portions at portions on one of surfaces of said base frame other than given portions of said leads, said die-pad portion and said frame portion; and
peeling off said first and second resists.

9. The method according to any one of claims 7 and 8, wherein the step of cutting the portions of said leads where the concave portions are formed includes the step of allowing portions selected from among all portions where the concave portions are formed, to remain uncut and connected.

10. A method of manufacturing a semiconductor device using the leadframe according to claim 1, the method comprising the steps of:
mounting semiconductor chips severally on respective die-pad portions of said leadframe;
electrically connecting electrodes of the respective semiconductor chips and a given number of external connection terminals among a plurality of external connection terminals constituting the corresponding lead portions of said leadframe severally by bonding wires;
sealing the respective semiconductor chips, the respective bonding wires and the respective lead portions with molding resin;
peeling off said adhesive tape; and
dividing said leadframe mounting the respective semiconductor chips thereon into individual semiconductor devices such that each of the semiconductor devices includes one of the semiconductor chips.

11. The method according to claim 10, wherein the step of sealing with molding resin is performed in accordance with a mass molding for performing resin sealing with respect to an entire surface on one side of said leadframe where the semiconductor chips are mounted, or an individual molding for performing resin sealing individually with respect to each of the semiconductor chips.

12. A semiconductor device comprising:
a die-pad;
a semiconductor chip mounted on said die-pad;
a plurality of leads arranged in the shape of a grid around said die-pad;
electrodes of said semiconductor chip being connected by bonding wires to upper surfaces of said leads;
said semiconductor chip, said bonding wires and said leads being sealed with molding resin; and
lower surfaces of said leads being exposed from a surface of said molding resin, and being formed as external connection terminals.
